(19) United States
(12) Patent Application Publication
(10) Pub. No.: US 2026/0173718 A1
(43) Pub. Date: Jun. 18, 2026

(54) APPARATUS AND METHOD FOR MANUFACTURING DISPLAY DEVICE

(71) Applicant: Samsung Display Co., Ltd., Yongin-si (KR)

(72) Inventors: Ki Sang YOO, Yongin-si (KR); Young Su KIM, Yongin-si (KR); Dong Jin PARK, Yongin-si (KR); Sang Hyun SONG, Yongin-si (KR); Jae Sang LEE, Yongin-si (KR); Joon Ik LEE, Yongin-si (KR); So Mi JUNG, Yongin-si (KR)

(21) Appl. No.: 19/326,400

(22) Filed: Sep. 11, 2025

(30) Foreign Application Priority Data
Dec. 12, 2024 (KR) 10-2024-0184608

(51) Int. Cl. H10K 59/80; H05K 1/18; H10H 29/01; H10K 59/82; H10K 59/88

(52) U.S. Cl. CPC H10K 59/8722; H05K 1/189; H10H 29/0364; H10K 59/82; H10K 59/88; H05K 2201/10128

(57) ABSTRACT

An apparatus and a method for manufacturing a display device are disclosed. A method for manufacturing a display device includes attaching an adhesive member to a surface of a third portion of a metal member of a display structure, the display panel including a flat first portion and a curved second portion located outside the first portion, and the metal member including a flat third portion overlapping with the first portion of the display panel, and a curved fourth portion overlapping with the second portion of the display panel; aligning the display structure and an attaching structure, the attaching structure including a plate with an alignment portion and a pad member on the plate; attaching the display structure to the pad member of the attaching structure; attaching a cover window to the display structure; and removing an adhesive force of the adhesive member by providing energy to the adhesive member.

### CROSS-REFERENCE TO RELATED APPLICATION

The present application claims priority to and the benefit of Korean Patent Application No. 10-2024-0184608, filed on Dec. 12, 2024 in the Korean Intellectual Property Office, the entire disclosure of which is incorporated herein by reference.

### BACKGROUND

### 1. Field

Aspects of embodiments of the present disclosure relate to an apparatus and method for manufacturing a display device.

### 2. Description of the Related Art

Electronic devices, such as smartphones, tablet PCs, digital cameras, laptop computers, navigation systems, and smart televisions, which provide images to users, include display devices. A display device may include a display panel for generating and displaying images and various input devices.

Display devices typically display images only on their front surface, but in recent years, display devices with curved portions on the side surfaces for displaying images have been developed. A curved display device may include a curved window, a curved display panel attached to the curved window, and a curved metal member attached to the curved display panel.

### SUMMARY

According to an aspect of embodiments of the present disclosure, an apparatus and method for manufacturing a display device can improve process efficiency while minimizing or reducing a defect rate during a process of attaching a cover window, a display panel, and a metal member.

However, aspects and objectives of the present disclosure are not limited to those mentioned above, and other aspects and objectives not explicitly stated will be clearly understood by those skilled in the art based on the following description.

According to one or more embodiments of the present disclosure, a method for manufacturing a display device comprises attaching an adhesive member to a surface of a third portion of a metal member of a display structure, the surface being opposite to a surface of the third portion facing a display panel of the display structure, wherein the display panel includes a flat first portion and a curved second portion located outside the first portion, and the metal member includes a flat third portion overlapping with the first portion of the display panel, and a curved fourth portion overlapping with the second portion of the display panel; aligning the display structure and an attaching structure, the attaching structure including a plate with an alignment portion and a pad member on the plate; attaching the display structure to the pad member of the attaching structure; attaching a cover window to the display structure; and removing an adhesive force of the adhesive member by providing energy to the adhesive member.

In an embodiment, the adhesive member is attached inward of an outermost edge of the third portion of the metal member.

In an embodiment, the adhesive member is in direct contact with the metal member of the display structure.

In an embodiment, the energy comprises light.

In an embodiment, the adhesive member and the pad member of the attaching structure include a silicone-based resin.

In an embodiment, the aligning the display structure and the attaching structure comprises aligning the display structure and the attaching structure using a lower imaging member and an upper imaging member located between the plate and the display structure.

In an embodiment, the aligning the display structure and the attaching structure comprises aligning the attaching structure such that the alignment portion of the plate matches the lower imaging member.

In an embodiment, the display panel includes alignment marks on the second portion, the metal member includes openings overlapping with the alignment marks of the display panel, and the aligning the display structure and the attaching structure comprises aligning the display structure such that the alignment marks of the display panel match the upper imaging member.

In an embodiment, the alignment marks of the display panel are recognizable by the upper imaging member through the openings of the metal member.

In an embodiment, the display structure further includes a flexible printed circuit board on the second portion of the display panel and bent toward a surface of the metal member opposite to the surface facing the display panel, and the flexible printed circuit board includes holes overlapping with the openings of the metal member.

In an embodiment, the alignment marks of the display panel are recognizable by the upper imaging member through the openings of the metal member and the holes of the flexible printed circuit board.

In an embodiment, the attaching structure and the display structure are aligned concurrently (e.g., simultaneously).

In an embodiment, the energy comprises heat.

In an embodiment, the adhesive member includes an acrylic-based resin, and the pad member of the attaching structure includes a metal material.

According to an aspect of one or more embodiments of the present disclosure, an apparatus for manufacturing a display device comprises a plate including an alignment portion; a pad member on the plate; an upper stage on the pad member; and a lower imaging member and an upper imaging member between the plate and the upper stage, wherein the alignment portion is located outside an outermost edge of the pad member.

In an embodiment, the plate and the pad member are integrally formed.

In an embodiment, the upper stage includes: an upper jig including a flat first portion, a second portion located outside the first portion and including a concave surface, and a third portion located outside the second portion; and a support member on a surface of the third portion of the upper jig facing the plate and arranged on a surface of the second portion of the upper jig facing the plate.

In an embodiment, the support member is movable outward of the upper jig so as not to overlap with the second portion of the upper jig.

In an embodiment, the support member includes a first support member positioned at an edge of a surface of the upper jig facing the plate, and a second support member at another edge of the surface of the upper jig facing the plate.

According to one or more embodiments of the present disclosure, an electronic device comprises a display device for displaying an image; and a processor for transmitting an image data signal for displaying the image to the display device, wherein a method for manufacturing the display device comprises attaching an adhesive member to a surface of a third portion of a metal member of a display structure, the surface being opposite to a surface of the third portion facing a display panel of the display structure, wherein the display panel includes a flat first portion and a curved second portion located outside the first portion, and the metal member includes a flat third portion overlapping with the first portion of the display panel and a curved fourth portion overlapping with the second portion of the display panel; aligning the display structure and an attaching structure, the attaching structure including a plate with an alignment portion and a pad member positioned on the plate; attaching the display structure to the pad member of the attaching structure; attaching a cover window to the display structure; and removing an adhesive force of the adhesive member by providing energy to the adhesive member.

According to the aforementioned and other embodiments of the present disclosure, a display structure and an attaching structure including a display panel and a metal member, which have been preformed to correspond to a shape of a cover window, may be precisely aligned. The display structure is fixed to the attaching structure by an adhesive member that adheres only to the flat portion of the metal member. Therefore, the display structure can be attached to the cover window in a precisely aligned state, preventing or substantially preventing adhesion defects from occurring. Accordingly, a manufacturing apparatus and method for a display device can be provided that reduce a defect rate of the display device and improve display quality.

However, aspects and effects of the present disclosure are not limited to those described above, and other aspects and effects of the present disclosure will be apparent from the following description.

### BRIEF DESCRIPTION OF THE DRAWINGS

The above and other aspects and features of the present disclosure will become more apparent by describing in further detail some embodiments thereof with reference to the attached drawings, in which:

FIG. 1 is a bottom view of a display device according to an embodiment;

FIG. 2 is a cross-sectional view, taken along the line X1-X1′, of the display device of FIG. 1;

FIG. 3 is a plan view of an attaching structure according to an embodiment;

FIG. 4 is a cross-sectional view, taken along the line X3-X3′, of the attaching structure of FIG. 3;

FIG. 5 is a bottom view of an upper stage according to an embodiment;

FIG. 6 is a cross-sectional view, taken along the line X5-X5′, of the upper stage of FIG. 5;

FIG. 7 is a cross-sectional view, taken along the line X7-X7′, of the upper stage of FIG. 5;

FIG. 8 is a diagram for explaining a task of attaching an adhesive film to a display structure;

FIG. 9 is a diagram for explaining a task of aligning the display structure and an attaching structure with the adhesive film attached;

FIGS. 10 and 11 are diagrams for explaining a task of attaching the display structure to a pad member of the attaching structure;

FIG. 12 is a diagram for explaining a task of separating the display structure from a first upper stage;

FIG. 13 is a diagram for explaining a task of attaching a cover window to the display structure;

FIG. 14 is a diagram for explaining a task of providing light to an adhesive member to eliminate an adhesive force of an adhesive member;

FIG. 15 is a diagram for explaining a task of recovering the adhesive member;

FIG. 16 is a diagram for explaining a task of separating a display device from a second upper stage;

FIG. 17 is a cross-sectional view, taken along the line X1-X1′, of a display device according to another embodiment;

FIG. 18 is a bottom view of a display device according to another embodiment;

FIG. 19 is a cross-sectional view, taken along the line X9-X9′, of the display device of FIG. 18;

FIG. 20 is a block diagram of an electronic device according to an embodiment; and

FIG. 21 illustrates schematic diagrams of electronic devices according to various embodiments.

### DETAILED DESCRIPTION

The present invention will now be described herein with reference to the accompanying drawings, in which some embodiments of the invention are shown. The present invention may, however, be embodied in different forms and is not to be construed as being limited to the embodiments set forth herein. Rather, these embodiments are provided so that this disclosure will be thorough and complete, and will fully convey the scope of the invention to those skilled in the art.

It is to be understood that when a layer is referred to as being “on” another layer or substrate, it may be directly on the other layer or substrate, or one or more intervening layers may also be present. The same reference numbers indicate the same components throughout the specification.

It is to be understood that, although the terms “first,” “second,” etc. may be used herein to describe various elements, these elements are not to be limited by these terms. These terms are used to distinguish one element from another element. For instance, a first element discussed below could be termed a second element without departing from the teachings of the present invention. Similarly, the second element could also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Herein, some embodiments will be described with reference to the accompanying drawings.

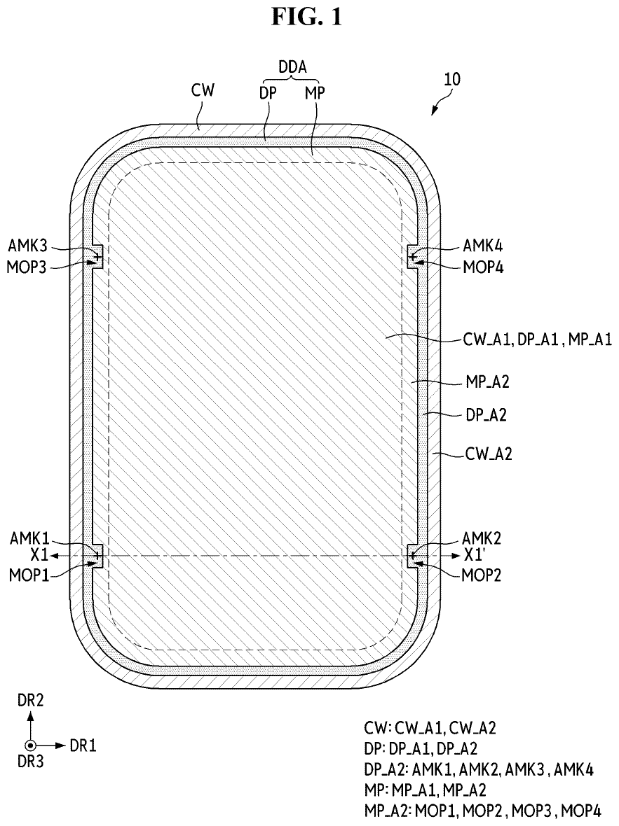

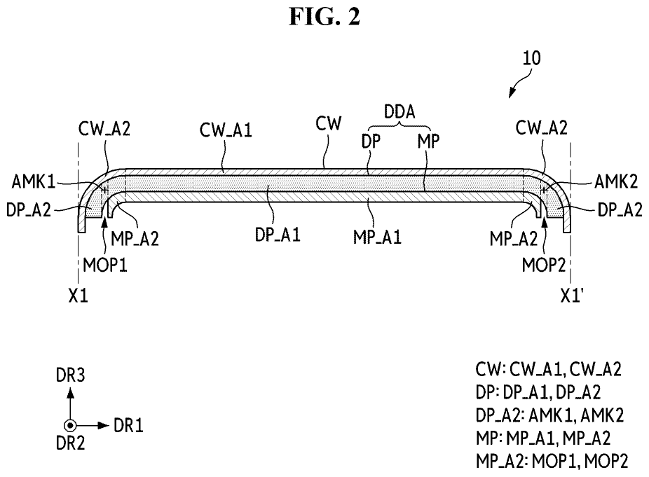

FIG. 1 is a bottom view of a display device according to an embodiment. FIG. 2 is a cross-sectional view, taken along the line X1-X1′, of the display device of FIG. 1.

A display device 10 according to an embodiment is a device for displaying a video or a still image and may be used as a display screen for various products.

The display device 10 may be an emissive display device, such as an organic light-emitting display device using organic light-emitting diodes (OLEDs), a quantum dot light-emitting display device including a quantum dot light-emitting layer, an inorganic light-emitting display device including an inorganic semiconductor, or a micro light-emitting display device using micro light-emitting diodes (micro-LEDs).

In this specification, a first direction DR1, which is a direction parallel to a short side of the display device 10 in a plan view, may correspond to, for example, a width direction of the display device 10. A second direction DR2, which is a direction parallel to long sides of the display device 10 in a plan view, may correspond to, for example, a height direction of the display device 10. A third direction DR3 may be a thickness direction of the display device 10. In an embodiment, the display device 10 may have a rectangular shape in a plan view.

Referring to FIGS. 1 and 2, the display device 10 may include a display structure DDA and a cover window CW positioned on the display structure DDA.

The display structure DDA may include a display panel DP and a metal member MP disposed below the display panel DP.

The display panel DP may be an emissive display panel including light-emitting elements. The display panel DP may include a flat first portion DP_A1 and a curved second portion DP_A2 positioned outside the first portion DP_A1. The second portion DP_A2 of the display panel DP may surround the first portion DP_A1 of the display panel DP. The display panel DP may include alignment marks positioned in the second portion DP_A2. A plurality of alignment marks of the display panel DP may be provided. As illustrated in FIG. 2, the display panel DP may include first, second, third, and fourth alignment marks AMK1, AMK2, AMK3, and AMK4 positioned in the second portion DP_A2 of the display panel DP. In one or more embodiments, the first and third alignment marks AMK1 and AMK3 may be positioned at an outer edge of a side of the display panel DP in the first direction DR1, and the second and fourth alignment marks AMK2 and AMK4 may be positioned at an outer edge of another side of the display panel DP in the first direction DR1. In one or more embodiments, the first and third alignment marks AMK1 and AMK3 may be positioned at an outer edge of a side of the display panel DP in the second direction DR2, and the second and fourth alignment marks AMK2 and AMK4 may be positioned at an outer edge of another side of the display panel DP in the second direction DR2.

The metal member MP may be disposed below the display panel DP and may shield electromagnetic interference and/or dissipate heat. The metal member MP may include a flat first portion MP_A1 overlapping with the first portion DP_A1 of the display panel DP, and a curved second portion MP_A2 positioned outside the first portion MP_A1 and overlapping with the second portion DP_A2 of the display panel DP. In an embodiment, the second portion MP_A2 of the metal member MP may surround the first portion MP_A1 of the metal member MP. The metal member MP may include openings MOP positioned at the outermost edge of the second portion MP_A2 and overlapping with the alignment marks AMK of the display panel DP. A plurality of openings MOP of the metal member MP may be provided. In an embodiment, as illustrated in FIGS. 1 and 2, the metal member MP may include first, second, third, and fourth openings MOP1, MOP2, MOP3, and MOP4 positioned in the second portion MP_A2 of the metal member MP and overlapping with the first, second, third, and fourth alignment marks AMK1, AMK2, AMK3, and AMK4, respectively, of the display panel DP. In one or more embodiments, the first and third openings MOP1 and MOP3 may be positioned at an outermost edge of a side of the metal member MP in the first direction DR1, and the second and fourth openings MOP2 and MOP4 may be positioned at an outermost edge of another side of the metal member MP in the first direction DR1. In one or more embodiments, the first and third openings MOP1 and MOP3 may be positioned at an outermost edge of one side of the display panel DP in the second direction DR2, and the second and fourth openings MOP2 and MOP4 may be positioned at an outermost edge of another side of the display panel DP in the second direction DR2.

The cover window CW may be disposed on the display structure DDA to cover an upper surface of the display panel DP of the display structure DDA. The cover window CW may include a flat first portion CW_A1 overlapping with the first portion DP_A1 of the display panel DP and a curved second portion CW_A2 positioned outside the first portion CW_A1 and overlapping with the second portion DP_A2 of the display panel DP. In an embodiment, the second portion CW_A2 of the cover window CW may surround the first portion CW_A1 of the cover window CW. The cover window CW may protect the upper surface of the display panel DP of the display structure DDA.

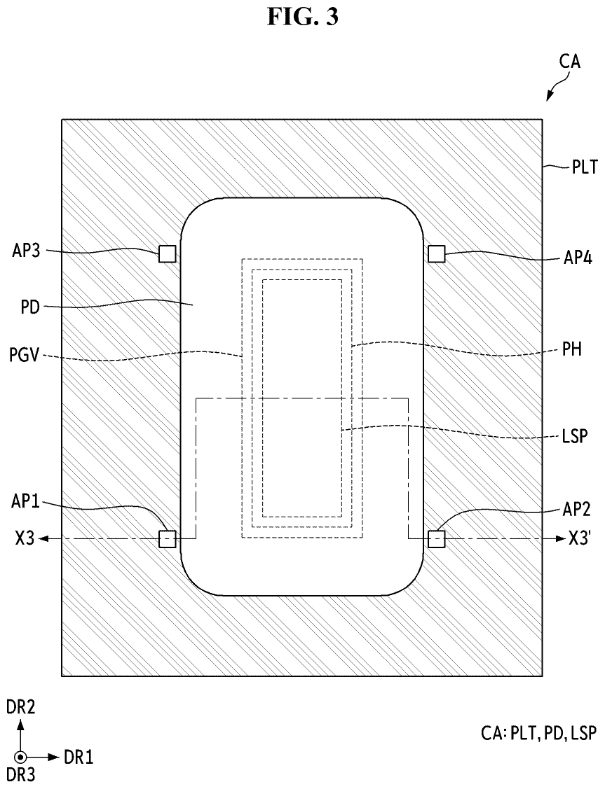

FIGS. 3 through 7 are diagrams for explaining an apparatus for manufacturing a display device according to an embodiment. The apparatus for a display device may include an attaching structure CA, an upper stage US positioned on the attaching structure CA, and a lower imaging member and an upper imaging member positioned between the attaching structure CA and the upper stage US.

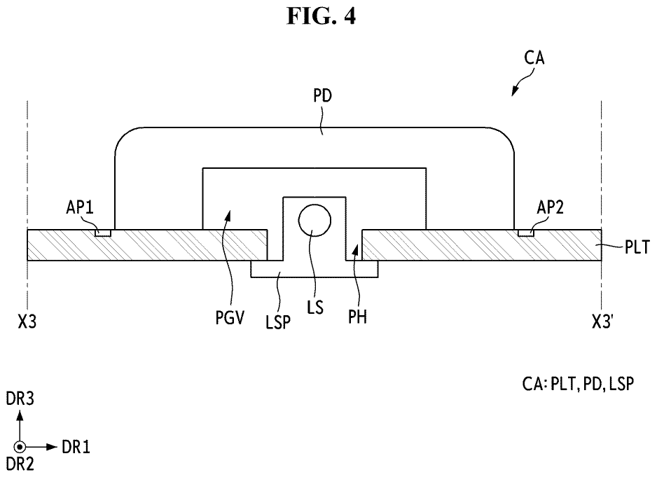

FIG. 3 is a plan view of an attaching structure according to an embodiment. FIG. 4 is a cross-sectional view, taken along the line X3-X3′, of the attaching structure of FIG. 3.

Referring to FIGS. 3 and 4, the attaching structure CA may include a plate PLT, a pad member PD positioned on the plate PLT, and a light source member LSP positioned under the plate PLT.

The plate PLT may include alignment portions. The alignment portions of the plate PLT may be positioned outside an outermost edge of the pad member PD. In an embodiment, as illustrated in FIG. 3, the plate PLT may include first, second, third, and fourth alignment portions AP1, AP2, AP3, and AP4, which are spaced apart from one another, and the first, second, third, and fourth alignment portions AP1, AP2, AP3, and AP4 may each be positioned outside the outermost edge of the pad member PD. In an embodiment, the plate PLT may include a hole PH that penetrates the plate PLT.

The pad member PD may be positioned on the plate PLT and may include a groove PGV recessed inward from the surface facing the plate PLT. The groove PGV of the pad member PD may overlap with the hole PH of the plate PLT. In an embodiment, the pad member PD may include a transparent silicone-based resin. In one or more embodiments, the pad member PD may be formed of a metal material with thermal conductivity.

The light source member LSP may be disposed below the plate PLT. The light source member LSP may overlap with the hole PH of the plate PLT and the groove PGV of the pad member PD and may protrude toward the pad member PD to be positioned inside the groove PGV defined by the pad member PD. The light source member LSP may include a light source LS. In one or more embodiments, the light source member LSP may further include a heat source.

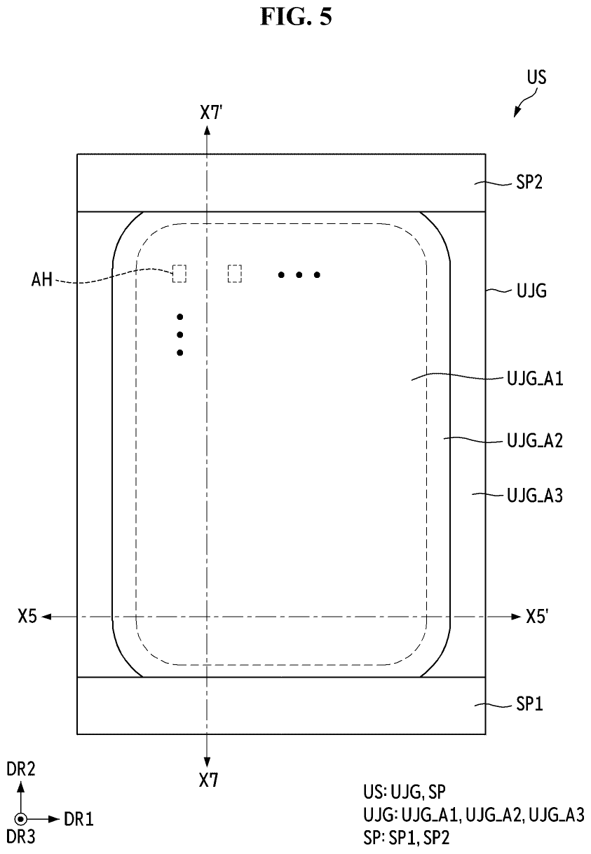

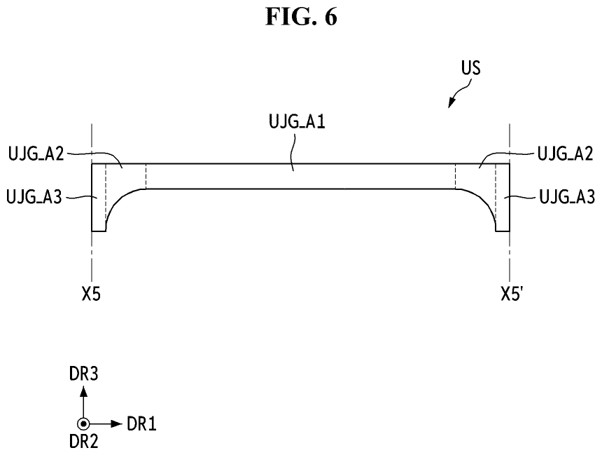

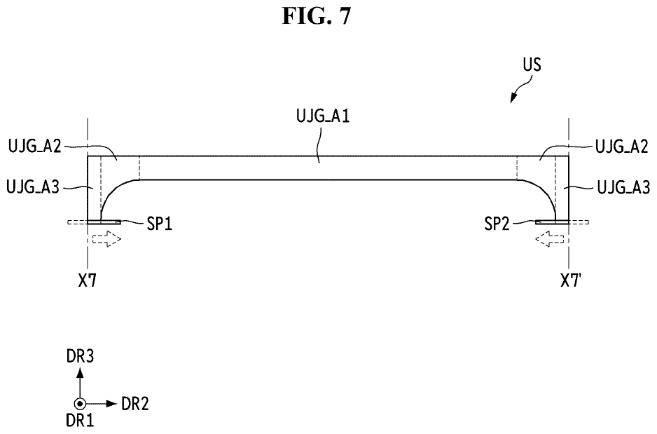

FIG. 5 is a bottom view of an upper stage according to an embodiment. FIG. 6 is a cross-sectional view, taken along the line X5-X5′, of the upper stage of FIG. 5. FIG. 7 is a cross-sectional view, taken along the line X7-X7′, of the upper stage of FIG. 5.

Referring to FIGS. 5 through 7, the upper stage US may include an upper jig UJG and a support member SP positioned under the upper jig UJG. The upper jig UJG may include a flat first portion UJG_A1, a second portion UJG_A2 positioned outside the first portion UJG_A1 and including a concave surface, and a third portion UJG_A3 positioned outside the second portion UJG_A2. In an embodiment, the third portion UJG_A3 of the upper jig UJG may surround the second portion UJG_A2. In an embodiment, the second portion UJG_A2 of the upper jig UJG may surround the first portion UJG_A1 of the upper jig UJG. The lower surfaces of the first and second portions UJG_A1 and UJG_A2 of the upper jig UJG in the third direction DR3 may correspond to a shape of a structure to be mounted. For example, when the display structure DDA is mounted on the upper stage US, the lower surfaces of the first and second portions US_A1 and US_A2 of the upper stage US may correspond to the upper surface of the display structure DDA. In an embodiment, the upper jig UJG may include a plurality of vacuum holes AH positioned in the first portion UJG_A1 of the upper jig UJG, and the upper stage US may support the structure mounted on the upper stage US by a vacuum suction method through the vacuum holes AH of the upper jig UJG. The support member SP may be positioned on the lower surface of the third portion UJG_A3 of the upper jig UJG in the third direction DR3 and may further be positioned on the lower surface of the second portion UJG_A2 of the upper jig UJG. The support member SP may move outward of the upper jig UJG so as not to overlap with the second portion UJG_A2 of the upper jig UJG. In an embodiment, as illustrated in FIG. 7, the support member SP may not overlap with the second portion UJG_A2 of the upper jig UJG and may be positioned on the third portion UJG_A3 and further outward of the upper jig UJG. The upper stage US may include a first support member SP1 positioned on a side of the lower surface of the upper jig UJG and a second support member SP2 positioned on another side of the lower surface of the upper jig UJG. The support member SP may physically support a structure mounted on the upper stage US. When the upper stage US operates in a vacuum environment, the support member SP may physically support a structure mounted on the upper stage US.

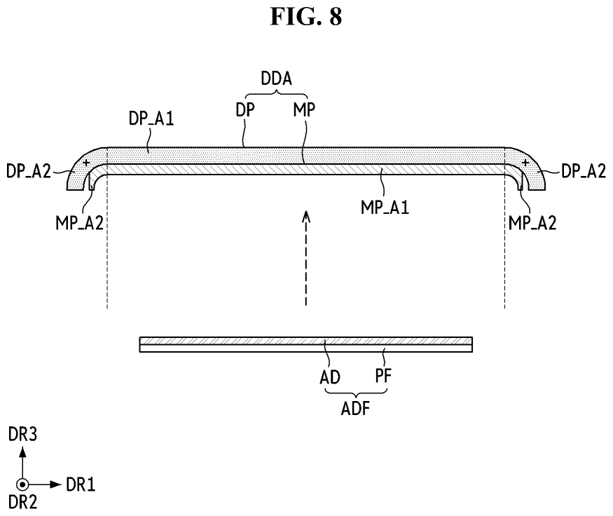

FIGS. 8 through 16 are diagrams for explaining a method for manufacturing a display device according to an embodiment.

FIG. 8 is a diagram for explaining a step, or task, of attaching an adhesive film to a display structure.

Referring to FIG. 8, an adhesive film ADF may include a protective film PF and an adhesive member AD positioned on the protective film PF. The protective film PF may protect the adhesive member AD. The adhesive member AD may be a energy-sensitive adhesive that loses its adhesive force when exposed to energy. In an embodiment, the adhesive member AD may be a light-sensitive adhesive that loses its adhesive force when exposed to light. In one or more embodiments, the adhesive member AD may be a heat-sensitive adhesive that loses its adhesive force when exposed to heat. In an embodiment, the adhesive member AD may include a silicone-based resin. In one or more embodiments, the adhesive member AD may include an acrylic-based resin. The adhesive member AD of the adhesive film ADF may be attached to a surface of a metal member MP of a display structure DDA that faces opposite to a display panel DP. The adhesive member AD of the adhesive film ADF may be attached to the first portion MP_A1 of the metal member MP. The adhesive member AD may be attached inward of an outermost edge of the first portion MP_A1 of the metal member MP. The adhesive member AD may directly contact the metal member MP of the display structure DDA.

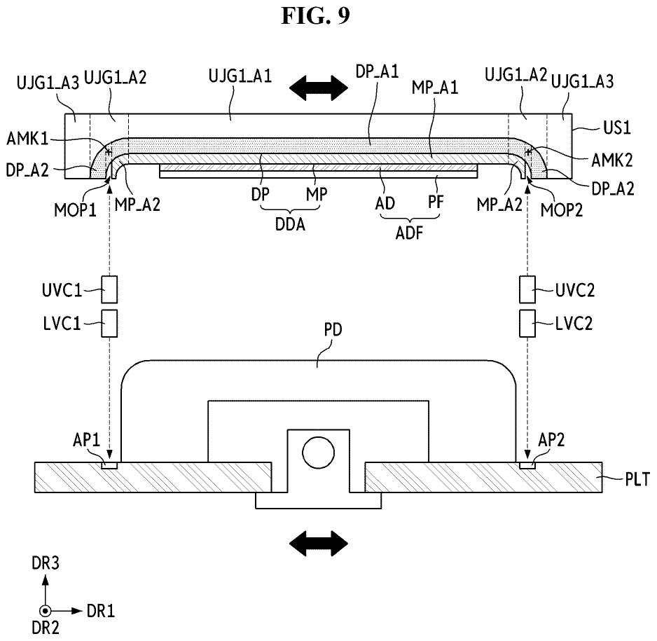

FIG. 9 is a diagram for explaining a step, or task, of aligning the display structure to which the adhesive film is attached and an attaching structure. Referring to FIG. 9, the display structure DDA with the adhesive film ADF attached may be seated and supported on a first upper stage US1 and aligned. The first upper stage US1 may include a first upper jig UJG1 and support members. The first upper jig UJG1 may include a flat first portion UJG1_A1, a second portion UJG1_A2 positioned outside the first portion UJG1_A1 and including a concave surface, and a third portion UJG1_A3 positioned outside the second portion UJG1_A2. The lower surfaces of the first and second portions UJG1_A1 and UJG1_A2 of the first upper jig UJG1 may correspond to the upper surface of the display panel DP. The lower surface of the first portion UJG1_A1 of the first upper jig UJG1 may correspond to the upper surface of a first portion DP_A1 of the display panel DP. The lower surface of the second portion UJG1_A2 of the first upper jig UJG1 may correspond to the upper surface of a second portion DP_A2 of the display panel DP. In an embodiment, the display structure DDA with the adhesive film ADF attached may be supported on the first upper stage US1 through vacuum suction. In one or more embodiments, the display structure DDA with the adhesive film ADF attached may be supported by support members SP1 and SP2 illustrated in FIGS. 5 and 7. The display structure DDA with the adhesive film ADF attached may be aligned as the first upper stage US1 moves in the first and second directions DR1 and DR2.

The display structure DDA with the adhesive film ADF attached may be aligned using an upper imaging member. In an embodiment, the upper imaging member may include a first upper imaging member UVC1, a second upper imaging member UVC2, a third upper imaging member (not shown), and a fourth upper imaging member (not shown). The display structure DDA with the adhesive film ADF attached may be aligned such that alignment marks AMK of the display panel DP may be aligned with the upper imaging member. The alignment marks AMK of the display panel DP may be recognized through openings MOP of the metal member MP. For example, as illustrated in FIG. 9, the display structure DDA with the adhesive film ADF attached may be aligned such that first and second alignment marks AMK1 and AMK2 of the display panel DP may be aligned with the first upper imaging member UVC1 and the second upper imaging member UVC2, respectively. The first and second alignment marks AMK1 and AMK2 of the display panel DP may be recognized by the first and second upper imaging members UVC1 and UVC2 through first and second openings MOP1 and MOP2 of the metal member MP, which overlap with the alignment marks. Although not illustrated in FIG. 9, the display structure DDA with the adhesive film ADF attached may be aligned such that third and fourth alignment marks of the display panel DP may be aligned with the third and fourth upper imaging members, respectively. The third and fourth alignment marks AMK3 and AMK4 of the display panel DP may be recognized by the third and fourth upper imaging members through the third and fourth openings MOP3 and MOP4 of the metal member MP, which overlap with the alignment marks, such that the display structure DDA with the adhesive film ADF attached may be aligned.

An attaching structure CA may be aligned using lower imaging members. The lower imaging members may include a first lower imaging member LVC1, a second lower imaging member LVC2, a third lower imaging member (not shown), and fourth lower imaging member (not shown). The attaching structure CA may be aligned such that alignment portions AP of a plate PLT may be aligned with the lower imaging members. For example, as illustrated in FIG. 9, the attaching structure CA may be aligned such that first and second alignment portions AP1 and AP2 of the plate PLT may be aligned with the first and second lower imaging members LVC1 and LVC2, respectively. Although not illustrated in FIG. 9, the attaching structure CA may be aligned such that the third and fourth alignment portions AP3 and AP4 of the plate PLT may be aligned with the third and fourth lower imaging members, respectively.

The display structure DDA with the adhesive film ADF attached may be aligned such that the first, second, third, and fourth alignment marks AMK1, AMK2, AMK3, and AMK4 of the display panel DP may be aligned with the first UVC1, second UVC2, third, and fourth upper imaging members, and the attaching structure CA may be aligned such that the first, second, third, and fourth alignment portions AP1, AP2, AP3, and AP4 of the plate PLT may be aligned with the first LVC1, second LVC2, third, and fourth lower imaging members. Therefore, the display structure DDA with the adhesive film ADF attached and the attaching structure CA can be accurately aligned.

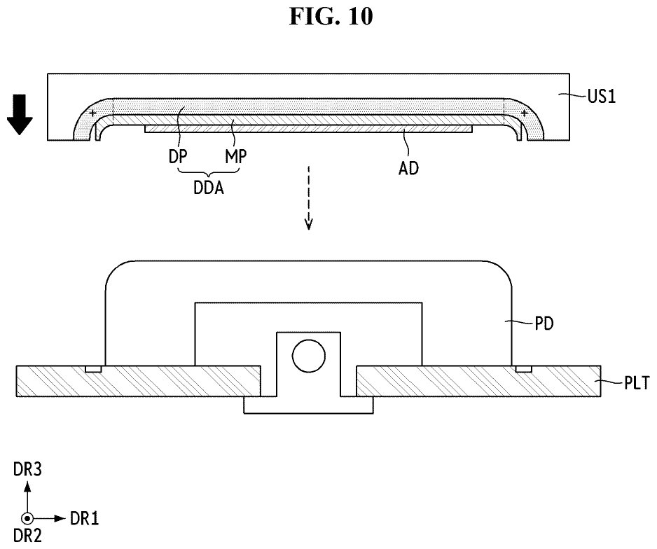

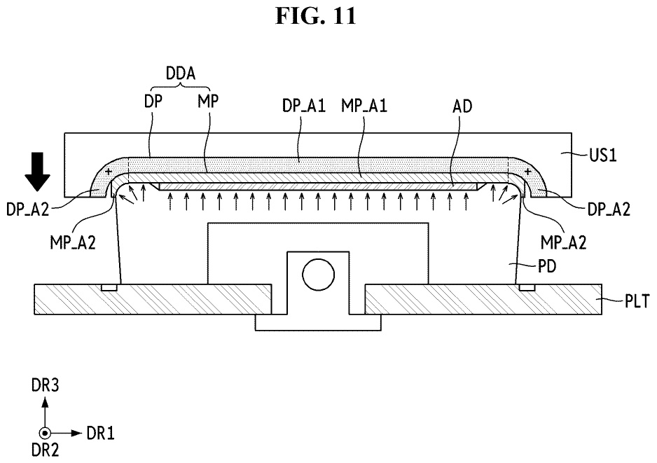

FIGS. 10 and 11 are diagrams for explaining a step, or task, of attaching the display structure to a pad member of an attaching structure. Referring to FIGS. 10 and 11, the display structure DDA may be pressed in a direction toward a pad member PD of an attaching structure CA while being supported by the first upper stage US1 and may be attached to the pad member PD of the attaching structure CA. The pad member PD of the attaching structure CA may first contact the adhesive member AD with the protective film PF removed from the display structure DDA and may then contact the metal member MP of the display structure DDA. The first portion MP_A1 of the metal member MP of the display structure DDA may first contact the pad member PD, and the second portion MP_A2 of the metal member MP may sequentially contact the pad member PD in a direction toward the outermost edge of the metal member MP. As the display structure DDA is pressed and attached toward the attaching structure CA by the first upper stage US1, the upper surface of the pad member PD may be deformed to correspond to the shape of the lower surface of the display structure DDA where the adhesive member AD is attached. The display structure DDA may be attached to the pad member PD of the attaching structure CA and fixed by the adhesive member AD. The display structure DDA is fixed to the pad member PD of the attaching structure CA by the adhesive member AD, and the display structure DDA can thereby maintain an accurately aligned state.

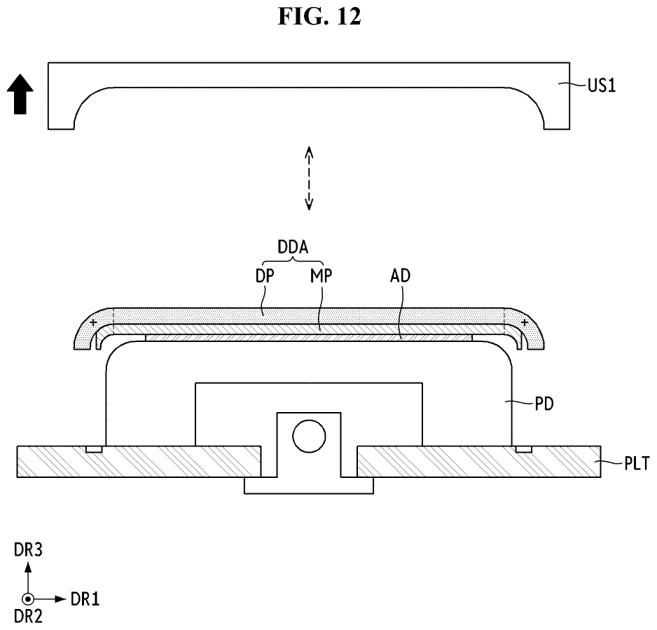

FIG. 12 is a diagram for explaining a step, or task, of separating the display structure from the first upper stage. Referring to FIG. 12, the first upper stage US1 may be separated from the display structure DDA and move in a direction opposite to the attaching structure CA. As the first upper stage US1 is separated from the display structure DDA, the pressure applied to the pad member PD may be released, and the pad member PD may return to its original shape.

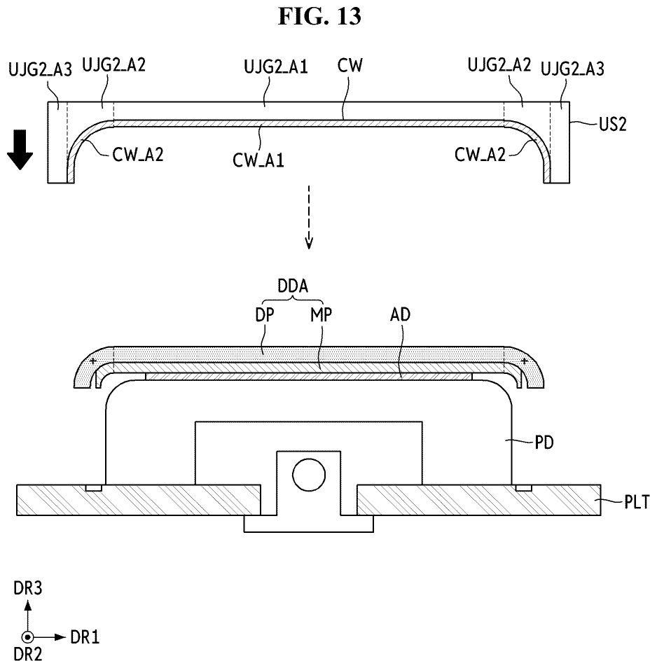

FIG. 13 is a diagram for explaining a step, or task, of attaching a cover window to the display structure. Referring to FIG. 13, a cover window CW may be supported by a second upper stage US2 and attached to the display structure DDA. The second upper stage US2 may include a second upper jig UJG2 and support members. The second upper jig UJG2 may include a flat first portion UJG2_A1, a second portion UJG2_A2 positioned outside the first portion UJG2_A1 and including a concave surface, and a third portion UJG2_A3 positioned outside the second portion UJG2_A2. The lower surfaces of the first and second portions UJG2_A1 and UJG2_A2 of the second upper jig UJG2 may correspond to the upper surface of the cover window CW. The lower surface of the first portion UJG2_A1 of the second upper jig UJG may correspond to the upper surface of the first portion CW_A1 of the cover window CW. The lower surface of the second portion UJG2_A2 of the second upper jig UJG2 may correspond to the upper surface of the second portion CW_A2 of the cover window CW. In an embodiment, the cover window CW may be supported on the second upper stage US2 by vacuum suction. In one or more embodiments, the cover window CW may be supported by the support members SP1 and SP2 illustrated in FIGS. 5 and 7. The cover window CW may be pressed in a direction toward the attaching structure CA while being supported on the second upper stage US2 and attached to the display structure DDA. The display structure DDA is fixed to the pad member PD of the attaching structure CA by the adhesive member AD and maintains an accurately aligned state, and the cover window CW can be attached accurately aligned to the display structure. Therefore, adhesion defects can be prevented or substantially prevented during the process of attaching the cover window CW to the display structure DDA. As a result, a defect rate of a display device can be reduced, and display quality can be improved.

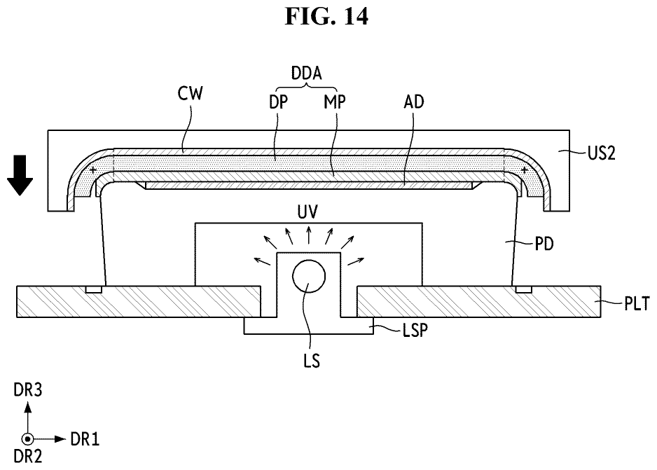

FIG. 14 is a diagram for explaining a step, or task, of providing light to the adhesive member to remove the adhesive force of the adhesive member. Referring to FIG. 14, the adhesive member AD attached below the display structure DDA may lose its adhesive force due to ultraviolet (UV) light provided from a light source LS of a light source member LSP located inside a groove PGV defined by the pad member PD. In one or more embodiments, the light source member LSP may further include a heat source, and the adhesive force of the adhesive member AD may be removed by the heat provided from the light source member LSP.

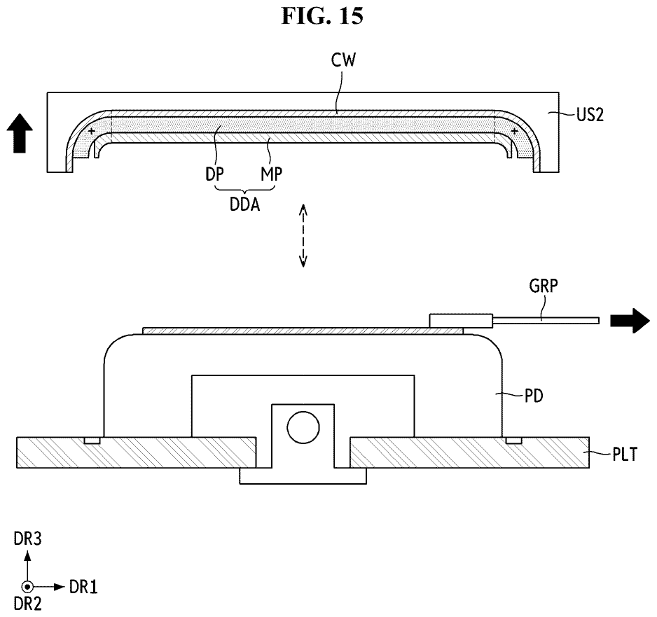

FIG. 15 is a diagram for explaining a step, or task of recovering the adhesive member. Referring to FIG. 15, the adhesive member AD with its adhesive force removed may be separated from the display structure DDA. The display structure DDA may be separated from the adhesive member AD as the second upper stage US2 moves in a direction opposite to the direction toward the attaching structure CA in the third direction DR3. The adhesive member AD with its adhesive force removed may remain on the pad member PD of the attaching structure CA and may be recovered by a gripper or the like.

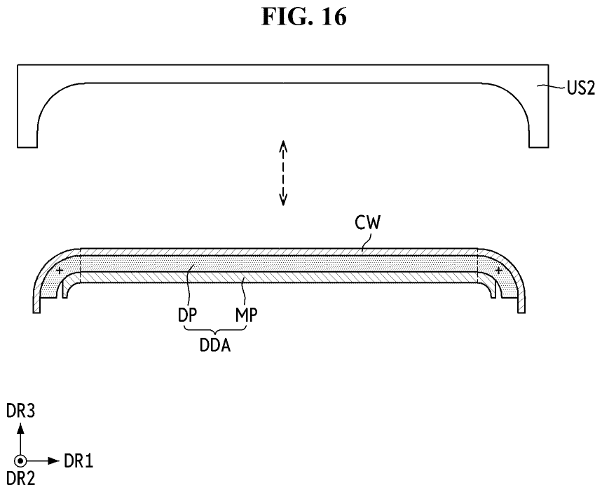

FIG. 16 is a diagram for explaining a step, or task, of separating the display device from the second upper stage. Referring to FIG. 16, the second upper stage US2 may be separated from the cover window CW attached to the display structure DDA.

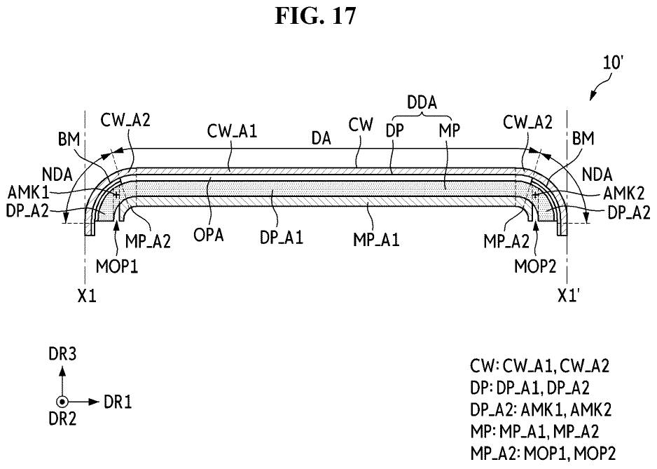

FIG. 17 is a cross-sectional view, taken along the line X1-X1′, of a display device according to another embodiment. Differences will be mainly described below, and redundant descriptions may be omitted.

Referring to FIG. 17, a display device 10′ may include a display area DA and a non-display area NDA surrounding the display area. Compared to the embodiment of FIGS. 1 and 2, the display device 10′ may further include an optical adhesive member OPA positioned between a cover window CW and a display structure DDA. The optical adhesive member OPA may be an optical clear adhesive (OCA) or an optical clear resin (OCR). In an embodiment, the display device 10′ may include a light-blocking member BM positioned on the surface of a second portion CW_A2 of the cover window CW facing a display panel DP and overlapping with the non-display area NDA. The light-blocking member BM may overlap with alignment marks positioned on a second portion DP_A2 of the display panel DP and openings MOP positioned on a second portion MP_A2 of a metal member MP. The light-blocking member BM may prevent or substantially prevent the alignment marks AMK of the display panel DP and the openings MOP of the metal member MP from being visible to a user.

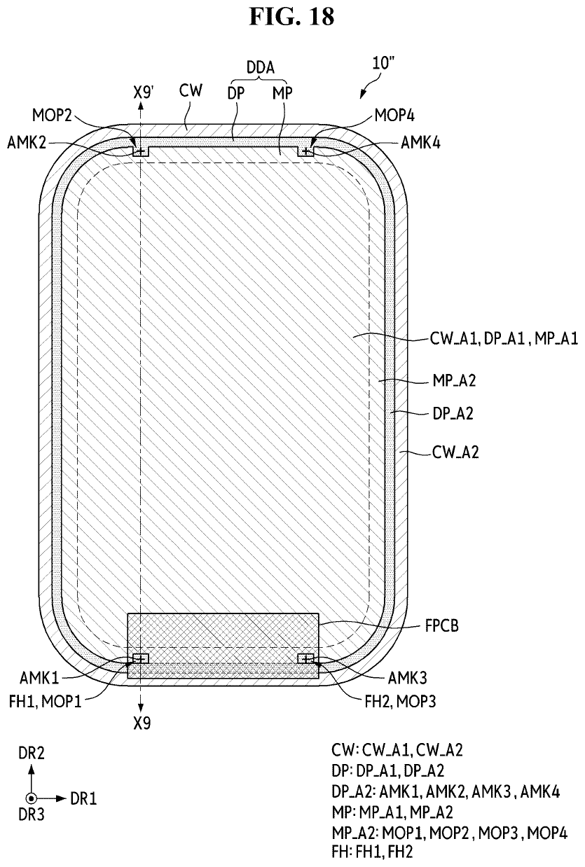

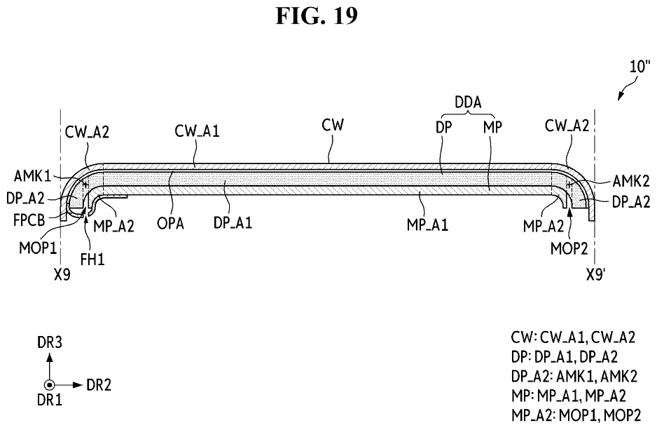

FIG. 18 is a bottom view of a display device according to another embodiment. FIG. 19 is a cross-sectional view, taken along the line X9-X9′, of the display device of FIG. 18. Differences will be mainly described below, and redundant descriptions may be omitted.

Referring to FIGS. 18 and 19, compared to the embodiment of FIGS. 1 and 2, a first alignment mark AMK1 and a third alignment mark AMK3 of a display panel DP of a display device 10″ may be positioned at an outer edge of a side of the display panel DP in the second direction DR2, and a second alignment mark AMK2 and a fourth alignment mark AMK4 may be positioned at an outer edge of another side of the display panel DP in the second direction DR2. First and third openings MOP1 and MOP3 of a metal member MP may be positioned at the outermost edge of the side of the display panel DP in the second direction DR2, and second and fourth openings MOP2 and MOP4 of the metal member MP may be positioned at the outermost edge of the another side of the display panel DP in the second direction DR2. The first, second, third, and fourth openings MOP1, MOP2, MOP3, and MOP4 of the metal member MP may overlap with the first, second, third, and fourth alignment marks AMK1, AMK2, AMK3, and AMK4 of the display panel DP.

A display structure DDA of the display device 10″ may further include a flexible printed circuit board FPCB positioned at the outer edge of the display panel DP and bent toward the surface of the metal member MP facing opposite to the display panel DP. The flexible printed circuit board FPCB may include a plurality of holes FH that overlap with openings MOP of the metal member MP and alignment marks AMK of the display panel DP. As illustrated in FIG. 18, the flexible printed circuit board FPCB may include a first hole FH1 and a second hole FH2 that overlap with the first opening MOP1 and the third opening MOP3, respectively, of the metal member MP. The first hole FH1 and the second hole FH2 of the flexible printed circuit board FPCB may overlap with the first alignment mark AMK1 and the third alignment mark AMK3, respectively, of the display panel DP.

The display devices according to one or more embodiments may be applied to various electronic devices. An electronic device according to an embodiment includes a display device according to any of the aforementioned embodiments and may further include modules or devices that provide additional functions beyond the display device.

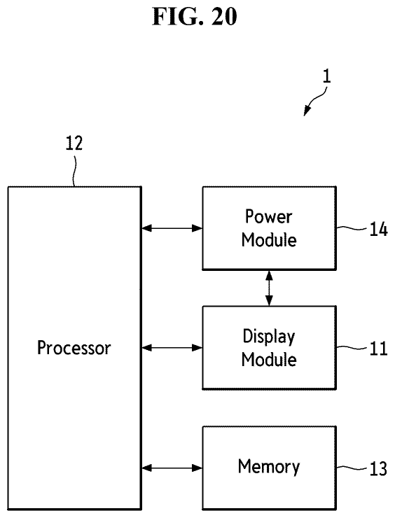

FIG. 20 is a block diagram of an electronic device according to an embodiment. Referring to FIG. 20, an electronic device 1 according to an embodiment may include a display module 11, a processor 12, a memory 13, and a power module 14.

The processor 12 may include at least one of a central processing unit (CPU), an application processor (AP), a graphics processing unit (GPU), a communication processor (CP), an image signal processor (ISP), or a controller.

The memory 13 may store data and information required for operation of the processor 12 or the display module 11. When the processor 12 executes an application stored in the memory 13, image data signals and/or input control signals may be delivered to the display module 11, and the display module 11 may process the received signals to output image information through a display screen.

The power module 14 may include a power supply module, such as a power adapter or a battery device, and a power conversion module that converts power supplied by the power supply module into power required for the operation of the electronic device 1.

At least one of the aforementioned components of the electronic device 1 may be included in a display device according to any of the aforementioned embodiments. Additionally, some of individual modules included functionally within a single module may be included in the display device, and others may be provided separately from the display device. For example, the display device may include the display module 11, while the processor 12, the memory 13, and the power module 14 may be provided as other devices included in the electronic device 1.

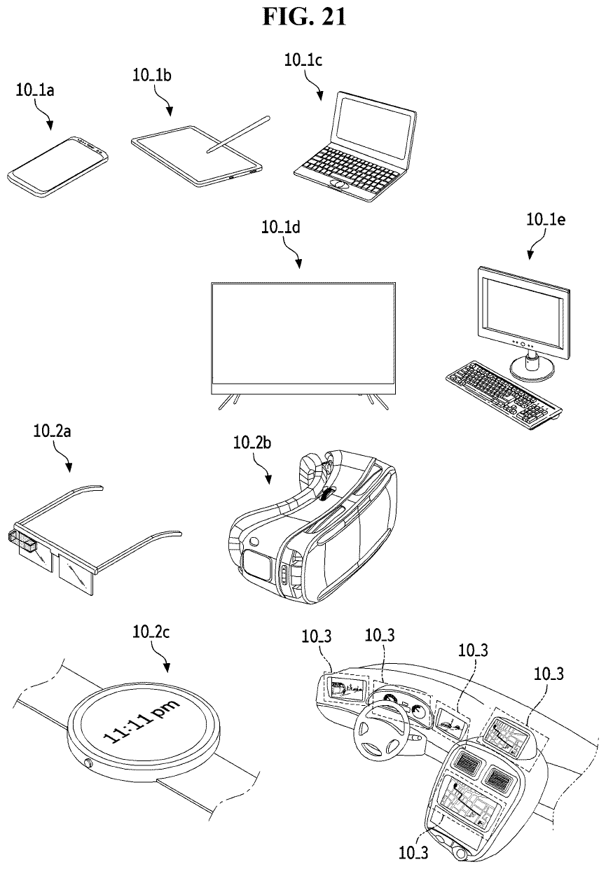

FIG. 21 illustrates schematic diagrams of electronic devices according to various embodiments.

Referring to FIG. 21, various electronic devices to which the display devices according to embodiments are applied may include image display electronic devices, such as a smartphone 10_1a, a tablet PC 10_1b, a laptop 10_1c, a TV 10_1d, and a desktop monitor 10_1e, wearable electronic devices that include a display module, such as smart glasses 10_2a, a head-mounted display 10_2b, and a smart watch 10_2c, and vehicle electronic devices 10_3 that include a display module, such as a center information display (CID) arranged on the instrument panel, center fascia, or dashboard of a vehicle, and a room mirror display.

In concluding the detailed description, those skilled in the art will appreciate that many variations and modifications can be made to the described embodiments without departing or substantially departing from the principles of the present invention. Therefore, the disclosed embodiments of the invention are used in a generic and descriptive sense and not for purposes of limitation.

What is claimed is:

1. A method for manufacturing a display device, the method comprising:
attaching an adhesive member to a surface of a third portion of a metal member of a display structure, the surface being opposite to a surface of the third portion facing a display panel of the display structure, wherein the display panel comprises a flat first portion and a curved second portion located outside the first portion, and the metal member comprises a flat third portion overlapping with the first portion of the display panel, and a curved fourth portion overlapping with the second portion of the display panel;
aligning the display structure and an attaching structure, the attaching structure comprising a plate including an alignment portion, and a pad member on the plate;
attaching the display structure to the pad member of the attaching structure;
attaching a cover window to the display structure; and
removing an adhesive force of the adhesive member by providing energy to the adhesive member.

2. The method of claim 1, wherein the adhesive member is attached inward of an outermost edge of the third portion of the metal member.

3. The method of claim 1, wherein the adhesive member is in direct contact with the metal member of the display structure.

4. The method of claim 1, wherein the energy comprises light.

5. The method of claim 4, wherein the adhesive member and the pad member of the attaching structure comprise a silicone-based resin.

6. The method of claim 1, wherein the aligning the display structure and the attaching structure comprises aligning the display structure and the attaching structure using a lower imaging member and an upper imaging member located between the plate and the display structure.

7. The method of claim 5, wherein the aligning the display structure and the attaching structure comprises aligning the attaching structure such that the alignment portion of the plate matches the lower imaging member.

8. The method of claim 5, wherein
the display panel comprises alignment marks located on the second portion,
the metal member comprises openings overlapping with the alignment marks of the display panel, and
the aligning the display structure and the attaching structure comprises aligning the display structure such that the alignment marks of the display panel match the upper imaging member.

9. The method of claim 7, wherein the alignment marks of the display panel are recognizable by the upper imaging member through the openings of the metal member.

10. The method of claim 7, wherein
the display structure further comprises a flexible printed circuit board on the second portion of the display panel and bent toward a surface of the metal member opposite to the surface facing the display panel, and
the flexible printed circuit board comprises holes overlapping with the openings of the metal member.

11. The method of claim 9, wherein the alignment marks of the display panel are recognizable by the upper imaging member through the openings of the metal member and the holes of the flexible printed circuit board.

12. The method of claim 1, wherein the attaching structure and the display structure are aligned concurrently.

13. The method of claim 1, wherein the energy comprises heat.

14. The method of claim 13, wherein
the adhesive member comprises an acrylic-based resin, and
the pad member of the attaching structure comprises a metal material.

15. An apparatus for manufacturing a display device, the apparatus comprising:
a plate comprising an alignment portion;
a pad member on the plate;
an upper stage on the pad member; and
a lower imaging member and an upper imaging member between the plate and the upper stage,
wherein the alignment portion is located outside an outermost edge of the pad member.

16. The apparatus of claim 14, wherein the plate and the pad member are integrally formed.

17. The apparatus of claim 14, wherein the upper stage comprises: an upper jig comprising a flat first portion, a second portion located outside the first portion and comprising a concave surface, and a third portion located outside the second portion; and a support member on a surface of the third portion of the upper jig facing the plate and arranged on a surface of the second portion of the upper jig facing the plate.

18. The apparatus of claim 16, wherein the support member is movable outward of the upper jig so as not to overlap with the second portion of the upper jig.

19. The apparatus of claim 16, wherein the support member comprises a first support member at an edge of a surface of the upper jig facing the plate, and a second support member at another edge of the surface of the upper jig facing the plate.

20. An electronic device comprising:
a display device for displaying an image; and
a processor for transmitting an image data signal for displaying the image to the display device,
wherein a method for manufacturing the display device comprises:
attaching an adhesive member to a surface of a third portion of a metal member of a display structure, the surface being opposite to a surface of the third portion facing a display panel of the display structure, wherein the display panel comprises a flat first portion and a curved second portion located outside the first portion, and the metal member comprises a flat third portion overlapping with the first portion of the display panel, and a curved fourth portion overlapping with the second portion of the display panel;
aligning the display structure and an attaching structure, the attaching structure comprising a plate including an alignment portion and a pad member on the plate;
attaching the display structure to the pad member of the attaching structure;
attaching a cover window to the display structure; and
removing an adhesive force of the adhesive member by providing energy to the adhesive member.
